(19) United States
(12) Patent Application Publication
(10) Pub. No.: US 2016/0126110 A1
(43) Pub. Date: May 5, 2016

(54) METHOD FOR MANUFACTURING THREE-DIMENSIONAL INTEGRATED CIRCUIT

(71) Applicant: PRINCO CORP., Hsinchu (TW)

(72) Inventor: Chih-kuang YANG, Hsinchu (TW)

(21) Appl. No.: 14/927,457

(22) Filed: Oct. 29, 2015

Related U.S. Application Data
(60) Provisional application No. 62/069,971, filed on Oct. 29, 2014.

(51) Int. Cl. H01L 21/48; H01L 23/00

(52) U.S. Cl. CPC H01L 21/481; H01L 24/81; H01L 24/11; H01L 2924/1533; H01L 2924/15172

(57) ABSTRACT

A method for manufacturing a three-dimensional integrated circuit is disclosed. The method includes: providing a substrate; forming at least one metal layer and at least one dielectric layer on the substrate; forming a plurality of electrical connection points on the metal layer; dicing to generate a plurality package units, each of the package units adhered to a diced substrate; reversing each of the package units and connecting each of the reversed package units to a surface of a wiring substrate to form an integrated substrate; and removing the diced substrate of each of the reversed package units. The present disclosure can improve an assembling process.

### CROSS REFERENCE TO RELATED APPLICATION

This patent application claims priority of U.S. Provisional Application Ser. No. 62/069,971, entitled “Method for Manufacturing Soft Organic Interposer on High Density Interconnect Substrate”, which is filed on Oct. 29, 2014, incorporated herein by reference.

### TECHNICAL FIELD OF THE INVENTION

The present invention relates to a manufacturing process field, and more particularly, to a method for manufacturing a three-dimensional integrated circuit.

### BACKGROUND OF THE INVENTION

A three-dimensional integrated circuit (3D IC, also called a 3D chip) is a structure by vertically stacking a plurality of chips and electrically connecting the chips electrically with through-silicon vias (TSVs).

A 3D IC mainly comprises a top die, a silicon interposer, and a high density interconnect (HDI) substrate which are stacked from top to bottom. In the process of manufacturing the 3D IC, the HDI substrate cannot provide an enough fan-out, such that the top die cannot be disposed on the HDI substrate directly. Accordingly, in the process of manufacturing the 3D IC, it is necessary to manufacture the silicon interposer firstly. Then, the silicon interposer is bonded to the HDI substrate after the silicon interposer is bonded to the top die. That is, the top die is disposed on the HDI substrate through the silicon interposer.

Consequently, there is a need to solve the above-mentioned problem that the top die cannot be disposed on the HDI substrate directly in the prior art.

### SUMMARY OF THE INVENTION

An objective of the present invention is to provide a method for manufacturing a three-dimensional integrated circuit which can solve the problem that the top die cannot be disposed on the HDI substrate directly in the prior art.

A method for manufacturing a three-dimensional integrated circuit of the present invention comprises: providing a substrate; forming at least one metal layer and at least one dielectric layer on the substrate; forming a plurality of electrical connection points on the metal layer; dicing to generate a plurality of package units, and each of the package units adhered to a diced substrate; flipping each of the package units, and bonding each of the flipped package units to a surface of a wiring substrate to form an integrated substrate, wherein the integrated substrate comprises a high density connection area and a low density connection area, the high density connection area comprises an area of an outer surface of each of the flipped package units, and the low density connection area comprises an area which is not covered by each of the flipped package unit; and removing the diced substrate of each of the flipped package units.

A method for manufacturing a three-dimensional integrated circuit of the present invention comprises: providing a first substrate; forming at least one metal layer and at least one dielectric layer on the first substrate; forming a plurality of electrical connection points on the metal layer to generate a package unit; flipping the package unit, and bonding the flipped package unit to a surface of a second substrate; removing the first substrate, and adhering a build-up film to the package unit, such that the package unit is embedded in the build-up film; and removing the second substrate, wherein the package unit and the build-up film together form an integrated substrate, the integrated substrate comprises a high density connection area and a low density connection area, the high density connection area comprises an area of an outer surface of the flipped package unit, and the low density connection area comprises an area excluding the outer surface of the flipped package unit.

A method for manufacturing a three-dimensional integrated circuit of the present invention comprises: forming a plurality of package units on a first substrate, and each of the package units comprising at least one metal layer and at least one dielectric layer; performing a flip-chip bonding to bond a plurality of top chips to the package units; performing a wafer molding to the top chips to form a molded top wafer; performing a flip-chip bonding to bond the molded top wafer to a surface of a second substrate; and removing the first substrate.

The present invention provides a method for bonding a high density film substrate to an organic build-up substrate, such that the 3D package structure of the present invention has a high density fan-out wiring ability and can be clamped easily to perform an assembly process.

### BRIEF DESCRIPTION OF THE DRAWINGS

FIGS. 1A-1H show a method for manufacturing a 3D IC in accordance with one embodiment of the present invention.

FIGS. 2A-2F show a method for manufacturing a 3D IC in accordance with another embodiment of the present invention.

FIGS. 3A-3H show a method for manufacturing a 3D IC in accordance with yet another embodiment of the present invention.

### DETAILED DESCRIPTION OF THE INVENTION

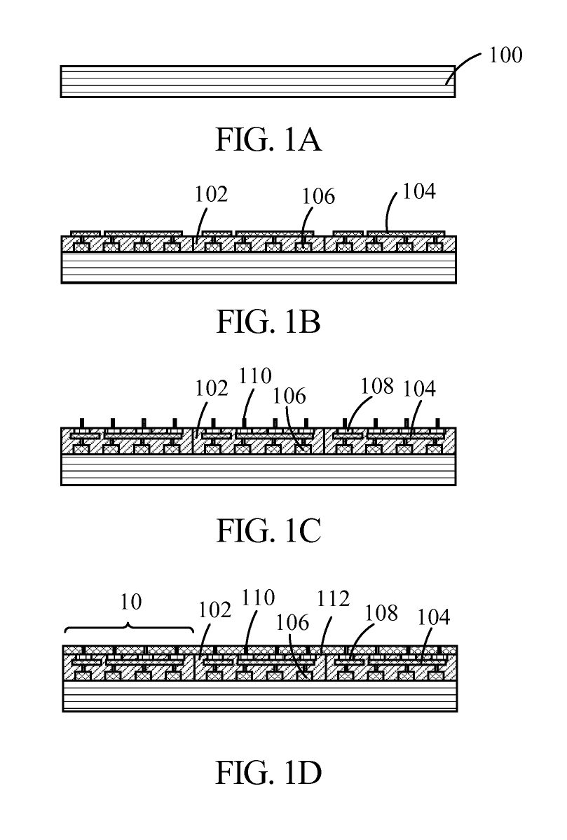

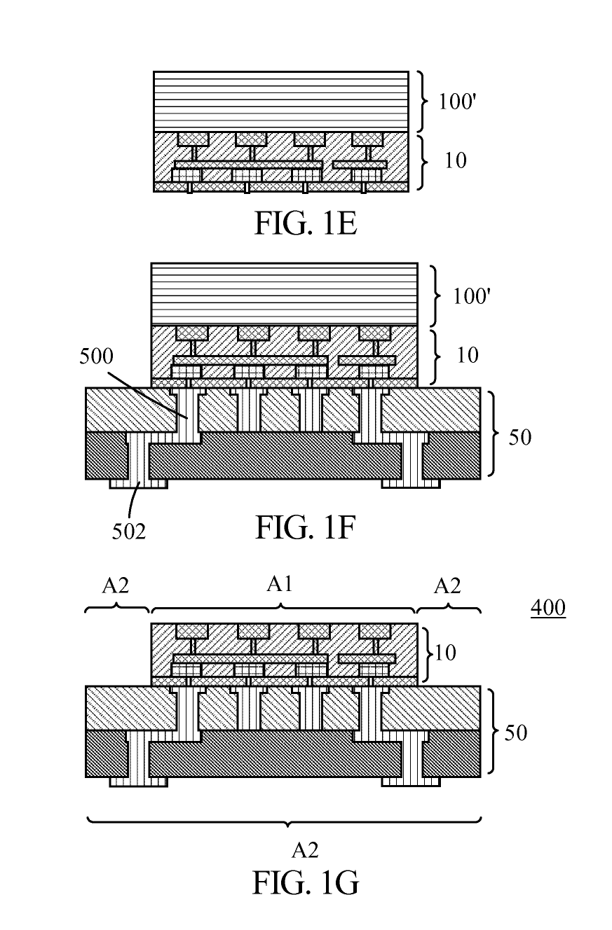

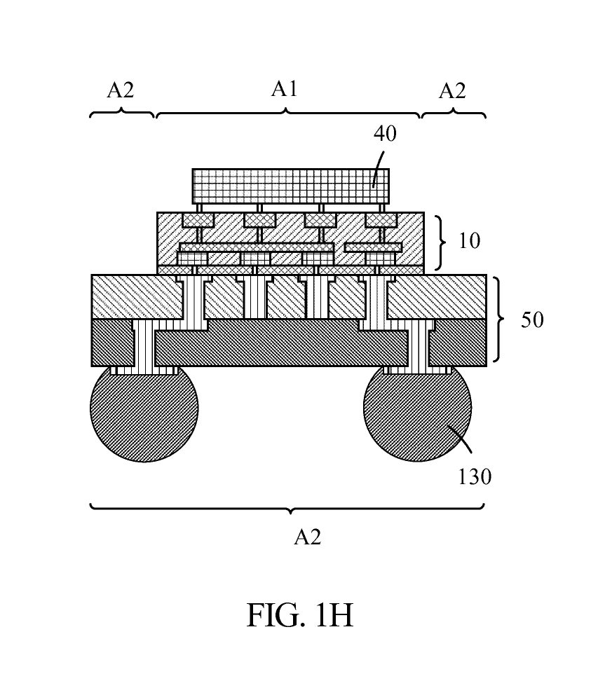

Please refer to FIGS. 1A-1H. FIGS. 1A-1H show a method for manufacturing a 3D IC in accordance with one embodiment of the present invention.

In FIG. 1A, a substrate 100 is provided. The substrate may include but not limit to a glass substrate or a metal substrate. The substrate 100 is made of a high temperature resistant and strong material. A melting temperature or a conversion temperature of the material is larger than 400° C.

In FIG. 1B, at least one metal layer and at least one dielectric layer 102 are formed on the substrate 100. The metal layer comprises a surface metal layer 104 and at least one inner metal layer 106. Since the substrate 100 is made of a high temperature resistant and strong material, fine lines are suitable to be formed on the substrate 100. A minimum pattern size of each of the metal layers (including the surface metal layer 104 and the inner metal layer 106) is less than 50 micrometers (μm). There is a predetermined control adhesive force (that is, the strength of the adhesive force can be controlled in advance when the dielectric layer 102 is formed) between the dielectric layer 102 and the substrate 100. In the following step, the inner metal layer 106 and the dielectric layer 102 can be peeled off from the substrate 100 by directly utilizing a mechanical force. Alternatively, the inner metal layer 106 and the dielectric layer 102 are peeled off from the substrate 100 by decreasing the adhesive force and then directly utilizing a mechanical force.

In FIG. 1C, a plurality of electrical connection points is formed on the surface metal layer 104. In the present embodiment, a plurality of pads 108 is formed on the surface metal layer 104, and a plurality of bumps 110 is formed on the pads 108. Since the substrate 100 is made of a high temperature resistant and strong material, fine lines are suitable to be formed on the substrate 100. A minimum pattern size of each of the pads 108 is less than 50 μm.

In FIG. 1D, a glue film 112 is formed on the bumps (i.e. the electrical connection points) 110. It is noted that a plurality of package units is formed on the substrate 100. Each of the package units will bond a chip to a substrate or a carrier in the following steps. In the present embodiment, the bumps 110 do not protrude from a surface of the glue film 112. In another embodiment, the bumps 110 may protrude from the surface of the glue film 112. As mentioned above, since the substrate 100 is made of a high temperature resistant and strong material, fine lines are suitable to be formed on the substrate 100. A minimum pattern size of each of the metal layers (including the surface metal layer 104 and the inner metal layer 106) of the package units 10 or a minimum pattern size of each of the pads 108 of the package units 10 is less than 50 μm.

In FIG. 1E, the package units 10 are diced to be separated from each other, and the package units 10 are flipped. FIG. 1E shows that a flipped package unit 10 is adhered to a diced substrate 100′. A thickness of the package unit 10 is less than 100 μm. A predetermined control adhesive force is formed between the package unit 10 and the diced substrate 100′.

In FIG. 1F, the flipped package unit 10 is bonded to a surface of a wiring substrate 50. A method for bonding the flipped package unit 10 to the surface of the wiring substrate 50 includes but is not limited to a thermal compression bonding (TCB) method or an ultrasonic bonding method. The above-mentioned bonding comprises electrical bonding or electrical bonding. The wiring substrate 50 is made by a general printed circuit board manufacturing process. A minimum pattern size of each of metal layers 500 or pads 502 of the wiring substrate 50 is greater than 50 μm.

In FIG. 1D, the bumps 110 do not protrude from the surface of the glue film 112. In the present step, when the package unit 10 is bonded to the surface of the wiring substrate 50, the bumps 110 may protrude from the surface of the wiring substrate 50 by utilizing a bonding force and then correspondingly bond to the connection points on the wiring substrate 50.

Furthermore, in the present embodiment, the glue film 112 is formed to bond to the surface of the wiring substrate 50. In another embodiment, the step of forming the glue film 112 in FIG. 1D can be omitted. When the step in FIG. 1D is omitted, a step of forming an underfill layer is before the step of bonding the flipped package unit 10 to the surface of the wiring substrate 50, thereby bonding the flipped package unit 10 to the surface of the wiring substrate 50 via the underfill layer.

In another embodiment, the glue film 112 can be formed on the surface of the wiring substrate 50 instead of the surface of the package unit 10, and then the flipped package unit 10 is bonded to a surface of a wiring substrate 50 as shown in FIG. 1F. A method for bonding the flipped package unit 10 to the surface of the wiring substrate 50 includes but is not limited to a thermal compression bonding method or an ultrasonic bonding method. The above-mentioned bonding comprises electrical bonding or electrical bonding.

In the present embodiment, the package unit 10 is bonded to the wiring substrate 50. The wiring substrate 50 may be a printed circuit board, an organic substrate, or a high density interconnect (HDI) substrate. In another embodiment, the package unit 10 can be bonded to a carrier.

In FIG. 1G, the diced substrate 100′ is removed. As mentioned above, there is a predetermined control adhesive force between the package unit 10 and the diced substrate 100′. In the following step, the diced substrate 100′ can be removed by directly utilizing a mechanical force. Alternatively, the diced substrate 100′ can be removed by decreasing the adhesive force and then directly utilizing a mechanical force.

In FIG. 1H, a flip-chip bonding is performed to bond a chip 40 to the package unit 10, and a ball mounting is performed to form at least one ball pad 130 on the other one surface of the wiring substrate 50.

It is noted that the wiring substrate 50 and the package unit 10 are bonded to form an integrated substrate 400 in FIG. 1G. An area of the integrated substrate 400 for bonding connection points or components comprises a first area A1 and a second area A2. The first area A1 comprises an area of an outer surface of the package unit 10. The second area A2 comprises an area which is not covered by the package unit 10. Specifically, the second area A2 comprises a surface of the wiring substrate 50 (i.e. an upper surface of the wiring substrate 50 in FIG. 1G) which the package unit 10 contacts and is not covered by the package unit 10 and comprises a surface (i.e. a lower surface of the wiring substrate 50 in FIG. 1G) opposite to the surface (i.e. an upper surface of the wiring substrate 50 in FIG. 1G) of the wiring substrate 50 which the package unit 10 contacts. As shown in FIG. 1G, the first area A1 (i.e. the area of the outer surface of the package unit 10) is a high density connection area. Since the metal layer (including the surface metal layer 104 and the inner metal layer 106) or the pads 108 of the package unit 10 can be less than 50 μm, the metal layer (including the surface metal layer 104 and the inner metal layer 106) or the pads 108 of the package unit 10 are suitable to be bonded to small-sized connection points or high-performance components, for example, the chip 40 which is flip-chip bonded to the package unit 10 in FIG. 1H. As shown in FIG. 1G, the second area A2 (i.e. the area not covered by the package unit 10) is a low density connection area. The second area A2 is the surface of the wiring substrate 50. The wiring substrate 50 is made by a general printed circuit board manufacturing process. A minimum pattern size of each of the metal layers 500 or the pads 502 of the wiring substrate 50 is greater than 50 μm, so the metal layers 500 or the pads 502 of the wiring substrate 50 are suitable to be bonded to large-sized connection points or low-performance components, for example, the ball pad 130 in FIG. 1H. It is noted that only the surface (i.e. the lower surface of the wiring substrate 50 in FIG. 1H) opposite to the surface of the wiring substrate 50 (i.e. the upper surface of the wiring substrate 50 in FIG. 1H) which the package unit 10 contacts the low density is served as the low density connection area. In another embodiment, the surface of the wiring substrate 50 (i.e. the upper surface of the wiring substrate 50 in FIG. 1G) which the package unit 10 contacts and is not covered by the package unit 10 can be served as the low density connection area. Alternatively, the surface of the wiring substrate 50 (i.e. the upper surface of the wiring substrate 50 in FIG. 1G) which the package unit 10 contacts and is not covered by the package unit 10 and the surface (i.e. the lower surface of the wiring substrate 50 in FIG. 1G) opposite to the surface (i.e. the upper surface of the wiring substrate 50 in FIG. 1G) of the wiring substrate 50 which the package unit 10 contacts are served as the low density connection area in the meantime.

In summary, the high density connection area (the first area A1) of the integrated substrate 400 is utilized for bonding to the connection points with a minimum pattern size of less than 50 μm or the high-performance components, and the low density connection area (the second area A2) of the integrated substrate 400 is utilized for bonding to the connection points with a minimum pattern size of greater than 50 μm or the low-performance components.

In the prior art, it is necessary to manufacture the silicon interposer (corresponding to the package unit 10 of the present invention) firstly. Then, the silicon interposer (corresponding to the package unit 10 of the present invention) is bonded to the HDI substrate (corresponding to the wiring substrate 50 of the present invention) after the silicon interposer (corresponding to the package unit 10 of the present invention) is bonded to the top die (corresponding to the chip 40 of the present invention). In the present invention, the chip 40 can be bonded to the wiring substrate 50 via the above-mentioned steps in FIGS. 1A-1H. Specifically, in the present invention, the chip 40 can be directly bonded to the wiring substrate 50 via the process of manufacturing the package unit 10.

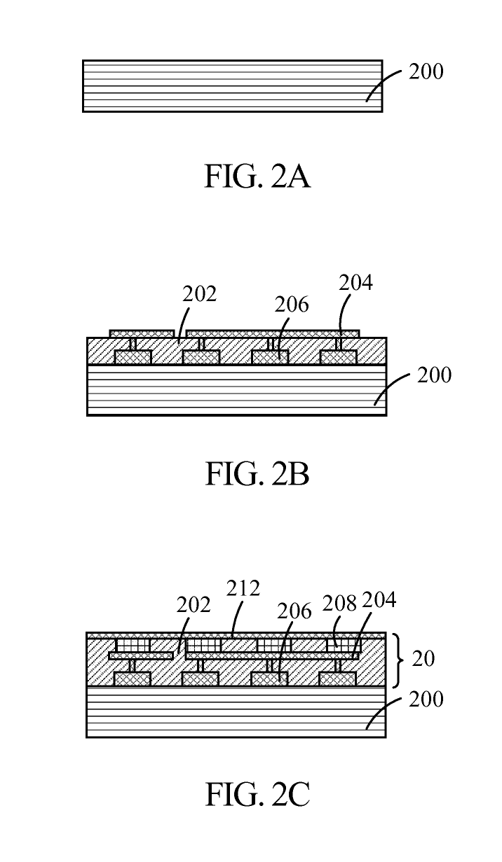

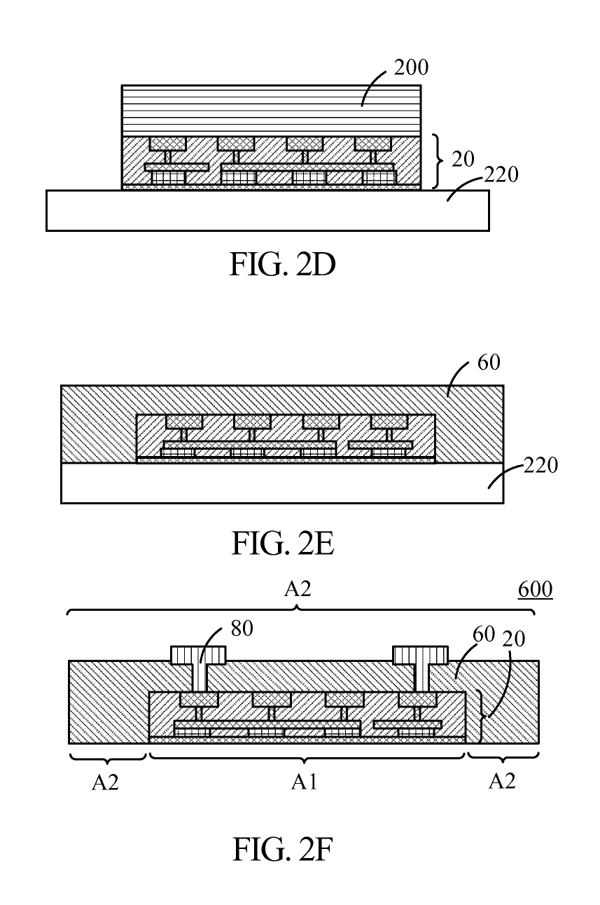

Please refer to FIGS. 2A-2F. FIGS. 2A-2F show a method for manufacturing a 3D IC in accordance with another embodiment of the present invention.

In FIG. 2A, a first substrate 200 is provided. The first substrate 200 may include but not limit to a glass substrate or a metal substrate. The first substrate 200 is made of a high temperature resistant and strong material. A melting temperature or a conversion temperature of the material is larger than 400° C.

In FIG. 2B, at least one metal layer and at least one dielectric layer 202 are formed on the first substrate 200. The metal layer comprises a surface metal layer 204 and at least one inner metal layer 206. Since the first substrate 200 is made of a high temperature resistant and strong material, fine lines are suitable to be formed on the first substrate 200. A minimum pattern size of each of the metal layers (including the surface metal layer 204 and the inner metal layer 206) is less than 50 micrometers (μm). There is a predetermined control adhesive force (that is, the strength of the adhesive force can be controlled in advance when the dielectric layer 202 is formed) between the dielectric layer 202 and the first substrate 200. In the following step, the inner metal layer 206 and the dielectric layer 202 can be peeled off from the first substrate 200 by directly utilizing a mechanical force. Alternatively, the inner metal layer 206 and the dielectric layer 202 are peeled off from the first substrate 200 by decreasing the adhesive force and then directly utilizing a mechanical force.

In FIG. 2C, a plurality of electrical connection points is formed on the surface metal layer 204. In the present embodiment, a plurality of pads 208 is formed on the surface metal layer 204, and a glue film 212 is formed on the pads 208. Since the first substrate 200 is made of a high temperature resistant and strong material, fine lines are suitable to be formed on the first substrate 200. A minimum pattern size of each of the pads 208 is less than 50 μm.

It is noted that a package unit 20 is formed on the first substrate 200. In the present embodiment, the pads 208 do not protrude from a surface of the glue film 212. In another embodiment, the pads 208 may protrude from the surface of the glue film 212. As mentioned above, since the first substrate 200 is made of a high temperature resistant and strong material, fine lines are suitable to be formed on the substrate 100. A minimum pattern size of each of the metal layers (including the surface metal layer 204 and the inner metal layer 206) of the package units 20 or a minimum pattern size of each of the pads 208 of the package units 20 is less than 50 μm.

In FIG. 2D, the package unit 20 is flipped, and the flipped package unit is bonded to a surface of a second substrate 220. A thickness of the package unit 20 is less than 100 μm. A method for bonding the flipped package unit 20 to the surface of the second substrate 220 includes but is not limited to a thermal compression bonding (TCB) method or an ultrasonic bonding method. The above-mentioned bonding comprises electrical bonding or electrical bonding.

In FIG. 2E, the first substrate 200 is removed, and a build-up film 60 such as an Ajinomoto Build-up Film (ABF) is adhered to and thermally compressed to the package unit 20, such that the package unit 20 is embedded in the build-up film 60. As mentioned above, there is a predetermined control adhesive force between the package unit 20 and the first substrate 200. Accordingly, the first substrate 200 can be removed by directly utilizing a mechanical force or decreasing the adhesive force between the package unit 20 and the first substrate 200.

A product which is produced by the manufacturing process of the present embodiment is shown in FIG. 2E or 2F. The package unit 20 may be utilized as an interposer. Then, a drilling process is performed to the build-up film 60, and at least one pad 80 is formed (as shown in FIG. 2F). A build-up process of a high density interconnect (HDI) substrate comprises the above-mentioned drilling process of the build-up film 60 and the process of forming the pad 80. A minimum pattern size in the build-up process is greater than 50 μm, and the build-up process is suitable to be bonded to large-sized connection points or low-performance components. Then, the second substrate 220 is removed, and the package unit 20 and the build-up film 60 together form an integrated substrate 600. An area of the integrated substrate 600 for bonding connection points or components comprises a first area A1 and a second area A2. A flip-chip bonding process can be performed to a surface of the integrated substrate 600. Since the drilling process, the build-up process, the process of removing the second substrate 220, and the flip-chip bonding process are prior art and thus omitted herein.

It is noted that the area of the integrated substrate 600 for bonding the connection points or the components comprises the first area A1 and the second area A2 in FIG. 2F. The first area A1 comprises an area of an outer surface of the package unit 20. The second area A2 comprises an area excluding the outer surface of the package unit 20. Specifically, the first area A1 (i.e. the area of the outer surface of the package unit 20) is a high density connection area. Since the metal layer (including the surface metal layer 204 and the inner metal layer 206) of the package unit 20 can be less than 50 μm, the metal layer (including the surface metal layer 204 and the inner metal layer 206) of the package unit 20 are suitable to be bonded to small-sized connection points or high-performance components, for example, the chip 40 which is flip-chip bonded to the package unit 10 in FIG. 1H. The second area A2 (i.e. the area excluding the outer surface of the package unit 20) is a low density connection area. A minimum pattern size in the second area A2 is greater than 50 μm, so the second area A2 is suitable to be bonded to large-sized connection points or low-performance components, for example, the ball pad 130 in FIG. 1H.

In summary, the high density connection area (the first area A1) of the integrated substrate 600 is utilized for bonding to the connection points with a minimum pattern size of less than 50 μm or the high-performance components, and the low density connection area (the second area A2) of the integrated substrate 600 is utilized for bonding to the connection points with a minimum pattern size of greater than 50 μm or the low-performance components.

An objective of the present embodiment is to provide the product as shown in FIG. 2F which can be utilized in various applications.

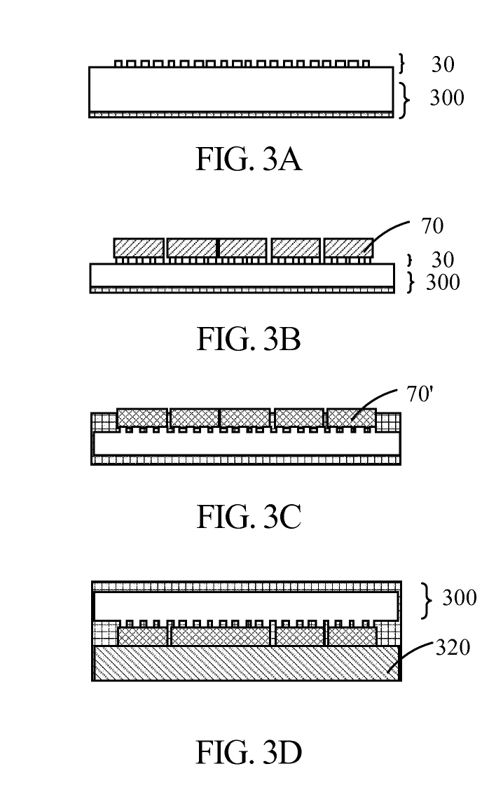

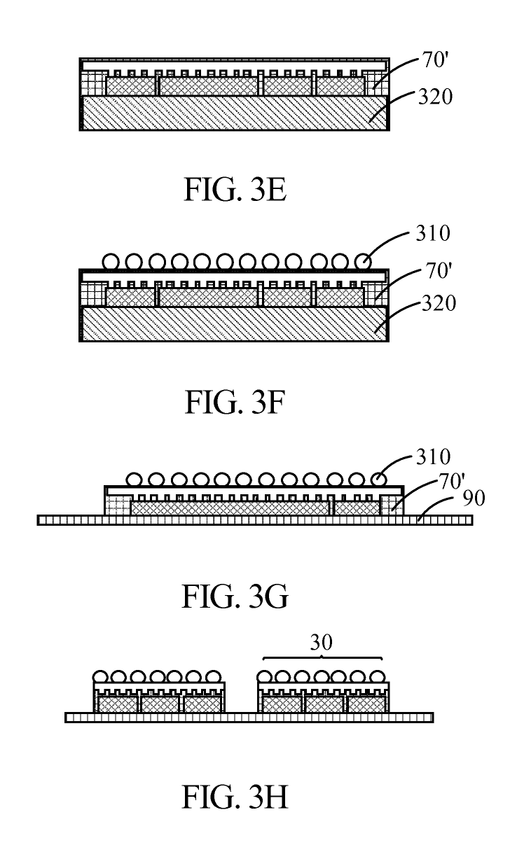

Please refer to FIGS. 3A-3H. FIGS. 3A-3H show a method for manufacturing a 3D IC in accordance with yet another embodiment of the present invention.

In FIG. 3A, a plurality of package units 30 is formed on a first substrate 300. Each of the package units 30 is utilized as an interposer. A structure of each of the package units 30 is the same as that of the package unit 10 shown in FIG. 1E. That is, each of the package units 30 may comprise at least one metal layer (including the surface metal layer 104 and at least one inner metal layer 106) and at least one dielectric layer 102. Since the first substrate 300 is made of a high temperature resistant and strong material, fine lines are suitable to be formed on the first substrate 300. A minimum pattern size of each of the metal layers (including the surface metal layer 104 and the inner metal layer 106) is less than 50 μm. There is a predetermined control adhesive force between the package units (the dielectric layer 102) and the first substrate 300. A thickness of each of the package units 30 is less than 100 μm.

In FIG. 3B, a flip-chip bonding is performed to bond a plurality of top chips to the package units 30.

In FIG. 3C, a wafer molding is performed to the top chips to form a molded top wafer 70′.

In FIG. 3D, a flip-chip bonding is performed to bond the molded top wafer 70′ to a surface of a second substrate 320.

In FIG. 3E, the first substrate 300 is removed. There is a predetermined control adhesive force between each of the package units 30 and the first substrate 300. Accordingly, the first substrate 300 can be removed by directly utilizing a mechanical force or decreasing the adhesive force between each of the package units 30 and the first substrate 300.

In FIG. 3F, a plurality of bumps 310 is formed on the molded top wafer 70′.

In FIG. 3G, the molded top wafer 70′ is transferred to a glue film 90.

In FIG. 3H, the package units 30 are diced to be separated from each other.

In the present invention, a high density film substrate (i.e. the package unit 10 or 20) is bonded to a high density interconnect (HDI) organic build-up substrate (i.e. the wiring substrate 50 or the build-up film 60) to form a 3D package structure which has a high mechanical strength and a high fan-out wiring ability. The method for manufacturing the high density film substrate is shown in FIGS. 1A-1E (the package unit 10) or FIGS. 2A-2C (the package unit 20). The package unit 10 and the package unit 20 have a high density fan-out wiring ability, and thus wirings of less than 5 μm or even less than 1 μm can be manufactured on the package unit 10 or the package unit 20 according to the steps in FIGS. 1A-1E or FIGS. 2A-2C. However, since a thickness of the high density film substrate is only about 100 μm, the high density film substrate is too flexible to be clamped. It is difficult to perform an assembly process (for example, the assembly process to the chip 40 in FIG. 1H) to the high density film substrate. The organic build-up substrate usually comprises wirings of greater than 10 μm and has a thicker structure (usually has a thickness of greater than 200 μm). Accordingly, the organic build-up substrate has a high mechanical strength, and it is easy to be clamped to perform an assembly process. The present invention provides a method for bonding the high density film substrate (the package unit 10 or 20) to the organic build-up substrate (the wiring substrate 50 or the build-up film 60), such that the 3D package structure of the present invention has a high density fan-out wiring ability and can be clamped easily to perform an assembly process.

The package units 30 which are manufactured by FIGS. 3A-3H are high density film substrates and complete package units. The package units 30 can be utilized in various products. For example, one of the package units 30 can be bonded to a wiring substrate (no shown) by performing a flip-chip bonding.

While the preferred embodiments of the present invention have been illustrated and described in detail, various modifications and alterations can be made by persons skilled in this art. The embodiment of the present invention is therefore described in an illustrative but not restrictive sense. It is intended that the present invention should not be limited to the particular forms as illustrated, and that all modifications and alterations which maintain the spirit and realm of the present invention are within the scope as defined in the appended claims.

What is claimed is:

1. A method for manufacturing a three-dimensional integrated circuit, comprising:
providing a substrate;
forming at least one metal layer and at least one dielectric layer on the substrate;
forming a plurality of electrical connection points on the metal layer;
dicing to generate a plurality of package units, and each of the package units adhered to a diced substrate;
flipping each of the package units, and bonding each of the flipped package units to a surface of a wiring substrate to form an integrated substrate, wherein the integrated substrate comprises a high density connection area and a low density connection area, the high density connection area comprises an area of an outer surface of each of the flipped package units, and the low density connection area comprises an area which is not covered by each of the flipped package unit; and
removing the diced substrate of each of the flipped package units.

2. The method for manufacturing the three-dimensional integrated circuit according to claim 1, wherein after the step of forming the electrical connection points on the metal layer, the method further comprises:
forming a glue film on the bumps.

3. The method for manufacturing the three-dimensional integrated circuit according to claim 1, wherein after the step of removing the diced substrate of each of the flipped package units, the method further comprises:
performed a flip-chip bonding to bond a chip 40 to one of the package units; and
performing a ball mounting to form at least one ball pad on the other one surface of the wiring substrate.

4. The method for manufacturing the three-dimensional integrated circuit according to claim 1, wherein the metal layer comprises a surface metal layer and at least one inner metal layer.

5. The method for manufacturing the three-dimensional integrated circuit according to claim 1, wherein there is a predetermined control adhesive force between the dielectric layer and the substrate.

6. The method for manufacturing the three-dimensional integrated circuit according to claim 5, wherein the diced substrate is removed by decreasing the predetermined control adhesive force.

7. The method for manufacturing the three-dimensional integrated circuit according to claim 1, wherein a thickness of each of the package units is less than 100 micrometers.

8. The method for manufacturing the three-dimensional integrated circuit according to claim 1, wherein the wiring substrate is a printed circuit board, an organic substrate, or a high density interconnect substrate.

9. The method for manufacturing the three-dimensional integrated circuit according to claim 1, wherein the high density connection area is utilized for bonding to connection points with a minimum pattern size of less than 50 micrometers or high-performance components, and the low density connection area is utilized for bonding to connection points with a minimum pattern size of greater than 50 μm or low-performance components.

10. A method for manufacturing a three-dimensional integrated circuit, comprising:
providing a first substrate;
forming at least one metal layer and at least one dielectric layer on the first substrate;
forming a plurality of electrical connection points on the metal layer to generate a package unit;
flipping the package unit, and bonding the flipped package unit to a surface of a second substrate;
removing the first substrate, and adhering a build-up film to the package unit, such that the package unit is embedded in the build-up film; and
removing the second substrate, wherein the package unit and the build-up film together form an integrated substrate, the integrated substrate comprises a high density connection area and a low density connection area, the high density connection area comprises an area of an outer surface of the flipped package unit, and the low density connection area comprises an area excluding the outer surface of the flipped package unit.

11. The method for manufacturing the three-dimensional integrated circuit according to claim 10, wherein after the step of forming the electrical connection points on the metal layer, the method further comprises:
forming a glue film on the electrical connection points.

12. The method for manufacturing the three-dimensional integrated circuit according to claim 10, wherein the metal layer comprises a surface metal layer and at least one inner metal layer.

13. The method for manufacturing the three-dimensional integrated circuit according to claim 10, wherein there is a predetermined control adhesive force between the dielectric layer and the first substrate.

14. The method for manufacturing the three-dimensional integrated circuit according to claim 13, wherein the first substrate is removed by decreasing the predetermined control adhesive force.

15. The method for manufacturing the three-dimensional integrated circuit according to claim 10, wherein a thickness of the package unit is less than 100 micrometers.

16. The method for manufacturing the three-dimensional integrated circuit according to claim 10, wherein the high density connection area is utilized for bonding to connection points with a minimum pattern size of less than 50 micrometers or high-performance components, and the low density connection area is utilized for bonding to connection points with a minimum pattern size of greater than 50 μm or low-performance components.

17. A method for manufacturing a three-dimensional integrated circuit, comprising:
forming a plurality of package units on a first substrate, and each of the package units comprising at least one metal layer and at least one dielectric layer;
performing a flip-chip bonding to bond a plurality of top chips to the package units;
performing a wafer molding to the top chips to form a molded top wafer;
performing a flip-chip bonding to bond the molded top wafer to a surface of a second substrate; and
removing the first substrate.

18. The method for manufacturing the three-dimensional integrated circuit according to claim 17, wherein after the step of removing the first substrate, the method further comprises:
forming a plurality of bumps on the molded top wafer;
transferring the molded top wafer to a glue film; and
dicing to separate the package units from each other.

19. The method for manufacturing the three-dimensional integrated circuit according to claim 17, wherein the metal layer comprises a surface metal layer and at least one inner metal layer.

20. The method for manufacturing the three-dimensional integrated circuit according to claim 17, wherein there is a predetermined control adhesive force between the dielectric layer and the first substrate.

21. The method for manufacturing the three-dimensional integrated circuit according to claim 20, wherein the first substrate is removed by decreasing the predetermined control adhesive force.

22. The method for manufacturing the three-dimensional integrated circuit according to claim 17, wherein a thickness of the package unit is less than 100 micrometers.
